(19) United States
(12) Patent Application Publication
(10) Pub. No.: US 2023/0348323 A1
(43) Pub. Date: Nov. 2, 2023

(54) METHOD FOR PRODUCING RAISED STRUCTURES ON GLASS ELEMENTS, AND GLASS ELEMENT PRODUCED ACCORDING TO THE METHOD

(71) Applicant: SCHOTT AG, Mainz (DE)

(72) Inventors: Andreas Ortner, Gau-Algesheim (DE); Fabian Wagner, Mainz (DE); Markus Heiss-Chouquet, Bischofsheim (DE); Michael Drisch, Mainz (DE); Vanessa Glässer, Mainz (DE); Annika Hörberg, Mainz (DE); Ulrich Peuchert, Bodenheim (DE); Jens Ulrich Thomas, Mainz (DE); Ville Polojarvi, Tampere (FI); Antti Määttänen, Tampere (FI)

(73) Assignee: SCHOTT AG, Mainz (DE)

(21) Appl. No.: 18/349,531

(22) Filed: Jul. 10, 2023

Related U.S. Application Data
(63) Continuation of application No. PCT/EP2021/087669, filed on Dec. 27, 2021.

(30) Foreign Application Priority Data
Jan. 8, 2021 (DE) 10 2021 100 180.3

(51) Int. Cl. C03C 23/00; C03C 15/00

(52) U.S. Cl. CPC C03C 23/0025; C03C 15/00

(57) ABSTRACT

A platelike glass element is provided that includes a first surface, a second surface opposite the first, and a hole that perforates the first surface. The hole extends in a longitudinal direction and a transverse direction, where the longitudinal direction is transverse to the first surface. The first surface has, at least partially around the hole, an elevation. The elevation has a feature selected from a group consisting of: a height of less than 5 μm that at least partially around the hole, a height greater than 0.05 μm, a height greater than 0.5 μm, a height greater than 1 μm, a height greater than 10 μm, a height less than 20 μm, a height less than 15 μm, a height less than 12 μm, and combinations thereof. The first surface has an average roughness value that is greater than 15 nm and less than 100 nm.

### CROSS REFERENCE TO RELATED APPLICATIONS

This application is continuation of International Application No. PCT/EP2021/087669 filed Dec. 27, 2021, which claims benefit under 35 USC § 119 of German Application No. 10 2021 100 180.3 filed Jan. 8, 2021, the entire contents of all of which are incorporated herein by reference.

### BACKGROUND

### 1. Field of the Invention

The invention relates to a method for producing structured glass elements, and also to a platelike glass element having a first surface, a second surface arranged opposite the first, and at least one hole which perforates at least one of the surfaces. The surface which is perforated by the hole has an average roughness value (Ra) which is between 15 nm and 100 nm, or defined elevations which have a height of less than 5 μm or more than 0.5 μm.

### 2. Description of Related Art

The precise structuring of glasses is of great interest in many fields of use. Among others, glass substrates are used in fields of camera imaging, especially 3D camera imaging, in electro-optics such as L(E)Ds, for example, microfluidics, optical diagnostics, sensing, such as pressure sensing, and diagnostic technology. Such areas of use relate, for example, to light sensors, camera sensors, pressure sensors, light-emitting diodes and laser diodes. Here, glass substrates usually in the form of thin wafers or glass membranes are used as structural elements. In order to be able to use such glass substrates in increasingly smaller technical applications or components, accuracies in the range of a few micrometers are needed. The working of the glass substrates here relates to apertures, cavities and channels in all kinds of shapes that are made in or through the glass substrates, and also to the structuring of surfaces of the substrates. Accordingly, structures in the range of a few micrometers must be made not only in the substrates but also on the surfaces of the substrates.

In order to be able to use the glass substrates in a wide field of uses, the working, moreover, ought not to leave behind any damage, residues—for example, material separated off or ablated or detached—or stresses in the marginal region or volume of the substrate. Furthermore, the method for producing these substrates ought to permit a highly efficient manufacturing process.

For structuring within a glass substrate, in order to produce openings, for example, there are a variety of methods that can be used. As well as water jet cutting and sandblasting through corresponding masks, ultrasonic machining is one established method. In respect of their scaling, however, these techniques are limited to small structures, which typically are around 400 μm in the case of ultrasonic machining and at least 100 μm in the case of sandblasting. Owing to the mechanical ablation, stresses in the glass are generated, associated with delaminations at the marginal region of the aperture, in the case of waterjet cutting and sandblasting. The two methods are fundamentally unusable for the structuring of thin glasses. For structuring of the surface of glass substrates as well, these methods are unsuitable in view of their predefined direction of erosion, and due to the coarse working.

In recent times, therefore, the use of laser sources has become established for the structuring of a wide variety of different materials. Using a wide diversity of different solid-state lasers, which operate with infrared (e.g. 1064 nm), green (532 nm) and UV (365 nm) wavelength or else with extremely short wavelengths (e.g. 193 nm, 248 nm), it is possible to make smaller structures in a glass substrate than is possible using the aforesaid mechanical methods. Since glasses, however, have a low thermal conductivity and also exhibit a high susceptibility to fracture, laser working in the production of very fine structures may also result in a high thermal load on the glass and hence in critical stresses up to the point of microcracks and deformations in the marginal region of apertures. Even relatively extensive structures at the surface of substrates may be generated, if at all, only at very high cost and complexity using the fine laser beam, which has a diameter of often just a few micrometers. The method is therefore of only limited suitability for use in the industrial manufacture of substrates which require specific surface structuring.

This relates in particular to components and/or substrates which specifically at the surface require a defined topography—for example, a reinforced margin for attachment to a fastening element—or specific structures having defined heights for the purpose of generating a distance between two components, as is the case, for example, with electro-optical transducers or functionalities. Such components enable the establishment of a defined distance between, for example, active and passive components, or contribute to the encasement and the protection of electromagnetic transducers/emitters/receivers, etc.

The distance which these components are able to provide is limited, however, by the manufacturing process, meaning that it is possible only at very high cost and through a great number of different process steps to produce fine structures in orders of magnitude of a few micrometers on substrate surfaces. For this reason, specific components are frequently used as spacers, which are applied to the substrate in later manufacturing steps, examples being spacers made of plastics, ceramics, metals or composites. An approach of this kind, however, gives rise to increased costs and also means that the component is composed of different materials—the substrate and the spacer. A unitary component made of glass, however, is employed preferably both for substrates and for spacers, however, owing to the cost-efficiency and the chemical resistance.

### SUMMARY

It is therefore the object of the invention to provide a glass substrate having a defined surface structure or topography and also fine structures running through the volume of the substrate. Furthermore, the intention was to be able to produce such a component at significantly reduced cost and complexity, and hence more cost-effectively, through an optimized method with regard to the generation of defined microstructures having low size tolerance.

The invention accordingly relates to a platelike glass element having a first surface, a second surface arranged opposite the first, and at least one hole which perforates at least one of the surfaces. The hole extends in a longitudinal direction and a transverse direction and the longitudinal direction of the hole is arranged transverse to the surface which is perforated by the hole. The surface which is perforated by the hole has at least one of the following features: the surface, at least partially around the hole, has at least one elevation, this elevation having a height of less than 5 μm, the surface has at least one plateau-like elevation with a height greater than 0.05 μm, preferably 0.5 μm, preferably greater than 1 μm, preferably greater than 10 μm and/or less than 20 μm, preferably less than 15 μm, preferably less than 12 μm, the surface has an average roughness value (Ra) which is greater than 15 nm, preferably greater than 25 nm, preferably greater than 40 nm and/or less than 100 nm, preferably less than 80 nm, preferably less than 60 nm.

These features have a number of advantages. Elevations which run preferably at least partially around the hole can serve as spacers between two components or glass elements. The elevation here may be understood as an elevation which is higher than a zero plane of the glass element, the zero plane comprising at least 51% of the first and/or second surface, preferably at least 70%, more preferably at least 90%, preferably at least 95%. Relative to the zero plane, therefore, there may also be one or more indentations configured which are deeper relative to the zero plane. The elevation here may preferably also be annular, or run annularly around the hole, in the form of an open ring, for example. In the case of an elevation height of less than 5 μm, a glass element of this kind can be used outstandingly in microsensor technology and can serve both as a substrate and as a spacer. Accordingly, only one component is needed, and corresponding transducers—electro-optical transducers, for example—can be produced more favorably.

Alternatively, the zero plane may be calculated by constructing an evaluation line (similar to an extension) around an individual feature at a selectable distance in all directions from its peripheral line, so forming a new line of similar shape but with greater area and periphery, and determining the mean profile height/thickness along this evaluation line. The reference height/thickness is obtained by repetition with ever greater distances from the original peripheral line of the feature as a limiting value for large distances.

The longitudinal direction is a direction which points from one side of the glass element to the other. The longitudinal direction may therefore also be termed thickness direction, or termed passage direction. Since the extent of a hole in longitudinal or thickness direction is limited by the thickness of the glass element, the dimensions of the hole in transverse direction are usually greater than in longitudinal direction specifically in the case of thin glass elements.

A further advantage is afforded by at least one plateau-like elevation with a height of preferably more than 1 μm. A plateau-like elevation of this kind may be configured, for example, as a margin, in which case the glass element may be configured as a membrane. In this way, the glass membrane could be fastened at the margin on an object. With the margin, the membrane becomes more mechanically stable, so reducing the risk of damage when it is fastened. It is therefore conceivable for the plateau-like elevation to have a height which is in fact greater than a thickness of the glass element. The height here runs preferably parallel to the thickness. It is, however, also conceivable for the height of the plateau-like elevation to be less than the thickness of the glass element, or to correspond to the thickness of the glass element.

The plateau-like elevation preferably has a height which is greater than 20 μm, preferably greater than 100 μm, preferably greater than 150 μm and/or less than 300 μm, preferably less than 250 μm, preferably less than 200 μm. This ensures that the glass element can be employed in a wide diversity of different applications by means of plateau-like elevations that differ in height.

A plateau of the plateau-like elevation may advantageously also have a structure. For example, the structure of the plateau may be configured to be complementary to the shape of a fastening element, allowing the fastening element to be fitted optimally in the structure of the plateau so that the glass element finds a very firm hold in the fastening element. According to one development, flanks of the plateau-like elevation(s) may have domelike indentations. As a result of the domelike indentations, the flanks of the plateau-like elevation(s) can be effectively protected from crack propagation or the crack propagation can be minimized, since the crack propagation is disrupted considerably by an uneven flank surface.

It is also conceivable, however, for the plateau of the plateau-like elevation to have a higher or lower roughness, or a higher or lower average roughness value (Ra), than the surface of the glass element. In this way, the plateau can be secured more effectively in a fastening element and at the same time the surface of the glass element may fulfil a different function—for example, it may provide improved flow properties for a fluid as a result of particularly low roughness and hence a relatively low resistance with respect to fluids.

Here, an average roughness value (Ra) of the surface of between 15 nm and 100 nm is particularly advantageous, since in this way the glass element can also have a matt surface, which is required for certain applications, or else is particularly smooth, thereby minimizing, for example, the resistance toward friction through other components or substances, such as fluids.

It is also possible for one or more plateau-like elevations to form a symmetrical or else an asymmetrical topography on the surface of the glass element. As a result it is possible that a specific structure on the surface of the glass element, formed by the plateau-like elevations, permits a specific usage—for example, a specifically shaped channel enables uses in microfluidics, or a specific structure into which a different component can be fitted, so that said component is unable to slip relative to the glass element. In this way it is possible, for example, to reduce a frictional stress due to shearing forces.

It is also advantageous if two or more elevations and/or plateau-like elevations have a comparable height, or preferably if a height of two or more plateau-like elevations and/or two or more elevations differs by less than 20 μm, preferably less than 15 μm, preferably less than 10 μm from one another. This ensures that a distance of the glass element from a different component is uniform.

The elevation preferably has at least one of the following features: the elevation surrounds the hole completely, the elevation is configured as an extension of the wall of the hole, an inside face of the elevation is at an acute angle to an outside face of the elevation, where the inside face faces the hole and the outside face faces away from the hole, the outside face is at an obtuse angle to the first surface which is perforated by the hole(s), the elevation is configured as a ridge around the hole, the elevation has lateral dimensions which are greater than 5 μm, preferably greater than 8 μm, preferably greater than 10 μm and/or less than 5 mm, preferably less than 3 mm, preferably less than 1 mm.

The elevation ideally surrounds the hole completely and/or is configured as a ridge around the hole. Ridges can be generated easily as part of the manufacturing of holes; in the best case, a ridge is formed directly during the generation of the hole, so that no additional cost or complexity is involved for generating the elevation, and the production costs can be reduced accordingly. It is advantageous if the elevation is configured as an extension of the wall of the hole, and therefore a uniform wall is formed by the hole and the elevation. In this case, an inside face of the elevation may be at an acute angle to an outside face of the elevation, with the inside face facing the hole and the outside face facing away from the hole. In this way, the glass element is stabilized mechanically in particular at those points where holes are formed, i.e., more particularly at locations where the glass element is potentially weaker mechanically. Accordingly, the elevations preferably serve not only as spacers, but also, in addition, for stabilizing the glass element with respect to mechanical stresses.

This mechanical stability may additionally be increased by the outside face being at an obtuse angle from the first surface which is perforated by the hole(s). In this way, the stability of the elevations with respect to shearing stresses is increased, such stress occurring, for example, as a result of a lateral movement of two components relative to one another. Furthermore, by means of obtuse angles, it is also possible for rounded-off structures, examples being flow channels, to be formed on the surface, thereby improving the flowability of fluids through these channels.

In one advantageous embodiment, the glass element has a thickness which is greater than 10 μm, preferably greater than 15 μm, preferably greater than 20 μm and/or less than 4 mm, preferably less than 2 mm, preferably less than 1 mm. A thickness of this kind makes it possible for two or more glass elements to be stacked one above another without requiring a lot of space. Furthermore, the glass element may be made flexible as a result of a low thickness, allowing it to be bent. Since other binding forces often play a key part as a result of low thickness, moreover, the glass element may be configured with a higher mechanical stability with respect to mechanical stress supplied from the outside. These advantages allow the glass element to be used, for example, in IC housings, biochips, sensors such as pressure sensors, for example, camera imaging modules and diagnostic technology devices.

In a further embodiment, the glass element has a transverse dimension of greater than 5 mm, preferably greater than 50 mm, preferably greater than 100 mm and/or less than 1000 mm, preferably less than 650 mm, preferably less than 500 mm. With such dimensions, the glass element can be used optimally as a component for microtechnology. In an embodiment with plateau-like elevations it is possible for the plateau-like elevations as well to have transverse dimensions corresponding to those of the glass element. In this way, the plateau-like elevations may also be configured as a reinforced margin encompassing the glass element for attachment to a fastening element, and may preferably act at the same time as stabilization with respect to mechanical stressing of the margin of the glass element.

It is also advantageous if the hole is configured as a channel which extends through the glass element from the first surface to the second surface and perforates both surfaces. A hole running through the glass element brings the advantage that whole structures as well, or multiple holes, can run through the glass element. With preference a plurality of holes or channels are arranged row-wise directly alongside one another, to form a larger hole, the size of which is determined at least by the sum total of the sizes of the individual holes arranged alongside one another. According to one preferred embodiment, the wall has domelike indentations.

The size of the larger hole may, however, also be greater than the sum of the holes arranged alongside one another. In this case, a width or transverse extent of the holes may extend parallel to the first and/or second surface, and the longitudinal direction or a depth of the holes may be configured perpendicularly to the first and/or second surface of the glass element. In this way, the glass element can have as many holes as desired, and in particular can have holes of any desired size, with a transverse extent running preferably perpendicularly to the depth of the holes. Through the introduction of the channels or continuous holes, if they are produced alongside one another, the glass element may also have a perforation, so making it possible in particular for parts of the glass element as well to be removable or separable.

It is also conceivable for an edge to be formed by a multiplicity of passages which extend through the glass element through the first surface to the second surface and which directly border one another. In that case, the edge forms a glass element outside edge which at least partly encompasses the glass element, or forms a glass element inside edge which at least partially encompasses the hole. The edge, furthermore, has a multiplicity of domelike indentations. A depth of the indentations is preferably aligned transversely to the depth of the hole and/or to the thickness of the glass element. It is also conceivable for a height of the edge to correspond to the thickness of the glass element. The domelike indentations ideally form a special structuring of the edge that is accompanied by multiple advantages. Hence the rounded-off structures or domes represent a particularly favorable shape for tensile stresses occurring at the edge surface to be relaxed down to the lowest points of the edge surface, specifically the lowest points of the domes. In this way the crack propagation at possible defects of the edge surface is effectively suppressed.

The edge preferably has a fractional area with convexly shaped regions which is less than 5%, preferably less than 2%. Ideally, therefore, there is a fractional area of concavely shaped regions, i.e., regions having domelike indentations, of greater than 95%, preferably greater than 98% of the edge surface. Concave here means that a curvature runs in the direction of the glass element, and convex means that a curvature runs away from the glass element, in other words in the direction of the hole. A depth of the domelike indentations is typically less than 5 μm, ideally in the case of transverse dimensions of preferably between 5-20 μm.

It is also conceivable for the edge to correspond to the wall of the hole. Therefore, the inside face of the elevation as well, particularly as an extension of the wall of the hole, can have the domelike indentations. The outside face of the elevation preferably also has domelike indentations. In this way, the elevation as well is protected from crack propagation.

It is also advantageous if the holes have a transverse dimension of 10 μm, preferably 20 μm, preferably 50 μm, preferably 100 μm. The transverse dimensions of the hole may also, however, be greater than at least 150 μm, preferably greater than 500 μm, or even up to 50 mm, meaning for example that other components as well, such as electronic conductors or piezoelectric components, can be installed in the holes. Such dimensions are advantageous particularly in the intended field of use of microsensor technology, especially when the elevations are configured annularly around the hole(s) and preferably have transverse dimensions of greater than 10 μm, preferably greater than 20 μm, preferably greater than 50 μm, preferably 100 μm. The transverse dimensions of the elevations may also, however, be greater than at least 150 μm, preferably greater than 200 μm, or even up to 300 μm. This is the case especially for a distance of inside faces of an elevation from one another, or of a diameter of an inside face of an elevation. In this way it is possible to ensure a distance of a glass element from a component arranged over it, particularly in the region of the hole(s).

It is possible for the elevation(s) to have a height which runs parallel to the longitudinal direction of the hole(s), and more particularly transversely to the first and/or second surface. In this way, the elevations project relative to the first and/or second surface of the glass element and more particularly form a bulge or a ridge relative to the first and/or second surface of the glass element. This allows the elevations to function as spacers which are able to preserve or produce a distance of a component arranged on the glass element relative to the first and/or second surface.

Furthermore, a width of the elevations and/or of the plateau-like elevations may be greater than the depth of the domelike indentations. The width of the elevations and/or plateau-like elevations preferably extends parallel to the first and/or second surface. Hence it is also possible for not only the elevations but also the plateau-like elevations to have domelike indentations and/or a concave shape at their respective flanks or walls, inside faces or outside faces.

The object is also achieved by a method for modifying a surface of a platelike glass element, whereby the glass element has a first surface, a second surface arranged opposite the first, and at least one hole which perforates at least one of the surfaces. Here, the hole extends in a longitudinal direction and a transverse direction, and the longitudinal direction of the hole is arranged transversely to the surface which is perforated by the hole. Preferably, a wall of the hole has a multiplicity of domelike indentations, and in the method: the glass element is provided, at least one filamentary channel is generated by a laser beam of an ultrashort pulse laser in the glass element, and a longitudinal direction of the channel runs transversely to the surface of the glass element, the surface of the glass element which is perforated by the channel is subjected to an etching medium which ablates glass of the glass element at an adjustable ablation rate, the channel being widened by the etching medium to form a hole, where the etching generates at least one of the following features of the surface which is perforated by the hole: the surface, at least partially around the hole, has at least one elevation, this elevation having a height of less than 5 μm, the surface has plateau-like elevations with a height of greater than 0.05 μm, preferably greater than 0.5 μm, preferably greater than 1 μm, preferably greater than 10 μm and/or less than 100% of the etching ablation, preferably less than 95%, preferably less than 90% of the etching ablation, the surface has an average roughness value (Ra) which is greater than 15 nm, preferably greater than 25 nm, preferably greater than 40 nm and/or less than 100 nm, preferably less than 80 nm, preferably less than 60 nm.

As a result of the method it is also possible to manufacture a glass element corresponding to the observations stated above, allowing the advantages stated above to be achieved. In a first method step, at least one glass element, in particular without holes, is provided. In a further, more particularly second step, at least one, but preferably two or more, and more preferably a multiplicity of damage sites is/are generated in the glass element, in order ideally to be able to configure perforation of the glass element through the damage sites. For this purpose, preferably a plurality of damage sites are generated alongside one another in such a way that a row of holes represents a larger structure. The damage sites are configured in particular as filamentary channels and in their longitudinal direction they run transversely to a first and/or second surface of the glass element. The channel here extends at least from one surface, and more perpendicularly from this surface, into the glass element and perforates at least this surface. Preferably, however, the channel extends from the first to the second surface and perforates both surfaces.

The hole(s) is/are generated by means of a laser beam of an ultrashort pulse laser in the glass element. The generation of the holes by means of the laser is based preferably on two or more of the steps stated below: the laser beam of the ultrashort pulse laser is directed onto one of the surfaces of the glass element and concentrated by a focusing optical system to form a protracted focus in the glass element, where the irradiated energy of the laser beam generates at least one filamentary damage site in the volume of the glass element, and the ultrashort pulse laser irradiates a pulse or a pulse package with at least two or more successive laser pulses onto the glass element, and preferably after the introduction of the filamentary damage site, the filamentary damage site is expanded to form a channel.

In this way, a multiplicity of channels are generated, and the channels, and more particularly their arrangement on or in the glass element, are selected such that numerous channels arranged alongside one another form an outline of a hole to be generated. The channels in this case may be arranged at a distance from one another which is greater than 2 μm, preferably greater than 3 μm, preferably greater than 5 μm and/or less than 100 μm, preferably less than 50 μm, preferably less than 15 μm. It is equally possible to vary a diameter of the channels between 10 μm and 100 μm.

In a further step, the surface which is perforated by at least one channel is subjected to an etching medium. With preference the entire glass element, more particularly the first and second surfaces, is/are subjected to this etching medium. It is advantageous if the etching medium is introduced into a container, such as a tank, a can or a tub, for example, and in particular, subsequently, one or more glass elements are held or immersed at least partially in the container and/or in the etching medium. The container in this case is formed preferably of a material which is substantially resistant toward the etching medium.

The etching medium may be gaseous, but is preferably an etching solution. According to this embodiment, therefore, the etching is carried out wet-chemically. This is favorable in order during etching to remove glass constituents from an inside channel face and/or from a surface of the damage sites and/or the surface of the glass element, for example the first and/or second surface. Glass constituents may of course also be dissolved out by the etching medium at an edge of the glass element.

Not only acidic but also alkaline solutions can be used for this purpose. Suitable acidic etching media are, in particular, HF, HCl, H₂SO₄, ammonium bifluoride, HNO₃ solutions or mixtures of these acids. Examples of basic etching media contemplated are KOH or NaOH alkalis. Ideally, the etching medium to be used is selected according to the glass element glass to be etched.

In one embodiment, therefore, the ablation rate may be adjusted through the choice of a combination of glass composition and composition of the etching medium (200). In the case of a glass of high calcium content, for example, an acidic etching medium is preferably selected, whereas in the case of a glass of lower calcium content, a basic etching medium is preferably employed, since too high a calcium content dissolved out of the glass by the etching can quickly oversaturate a basic, more particularly alkaline, etching medium and so the etching capacity of the etching medium would be lowered too quickly. On the other hand, in the case of an acidic etching medium and a glass with high silicate fraction, the ablation rate, in other words the etching rate, is very much higher than in the case of a basic etching medium, although the acidic etching medium is also neutralized very much more quickly by the substances already dissolved and hence the etching medium is spent or saturated with glass.

Accordingly, depending on glass composition, an acidic etching medium may be selected in order to establish a fast ablation rate, or a basic, more particularly alkaline, etching medium may be selected in order to establish a slow ablation rate. Generally speaking, silicatic glasses with low alkali metal content are particularly suitable for the modification of a glass surface in accordance with the invention. As mentioned above, excessive alkali metal contents make etching more difficult. In one development of the invention, therefore, the glass of the glass element is a silicate glass having an alkali metal oxide content of less than 17 percent by weight, and ideally a borosilicate glass.

For better controllability of the ablation, however, a slower ablation rate and/or a basic etching medium is preferred. It is possible as a result to achieve an ablation rate of less than 7 μm/h, with preference less than 5 μm/h, preferably less than 4 μm/h, preferably less than 3 μm/h and/or greater than 0.3 μm/h, preferably greater than 0.5 μm/h, preferably greater than 1 μm/h, preferably greater than 1.5 μm/h, and more particularly between 2 μm/h and 2.5 μm/h. An ablation rate of this kind advantageously leaves enough time to influence the etching medium, or the etching procedure, during the etching procedure.

In one embodiment, moreover, the ablation rate may be adjusted by means of additives. In that case it is possible, for example, to use substances of the following group, individually or in combination: surfactants, complexes and/or coordination compounds, radicals, metals and/or alcohols. Additives enable even more precise control of the etching capacity of the etching medium and in particular enable targeted control of the etching capacity for particular glasses or particular glass compositions.

The etching is carried out preferably at a temperature higher than 40° C., preferably higher than 50° C., preferably higher than 60° C. and/or lower than 150° C., preferably lower than 130° C., preferably lower than 110° C., and more particularly up to 100° C. This temperature creates sufficient mobility of the ions or constituents of the glass element glass to be dissolved out of the glass matrix.

Time is a further factor. Hence, for example, generally speaking, a higher ablation is achievable if the glass element is exposed to the etching medium for several hours, more particularly longer than 30 hours. On the other hand it is possible to limit the ablation by exposing the glass element to the etching medium for less than 30 hours, for example only 10 hours. In general at least one of the above-stated features of the glass element is generated by the introduction of damage sites and channels, and also the adjustability of the ablation rate and/or of the etching medium as a function of the temperature, the composition of the etching medium, the duration of the etching, and the composition of the glass element glass. For example, by establishing a relatively high ablation rate, more particularly of more than 2 μm per hour, an average roughness value (Ra) of between 15 nm and 100 nm can be achieved. At an ablation rate of about 2 μm per hour, elevations and/or plateau-like elevations can be generated with a height of more than 0.5 μm.

It is additionally possible for defined regions of the glass element to be shielded from the etching medium. This may be realized, for example, through the use of specific mounts by which the glass element is held in the volume of the etching medium. Additionally conceivable are specific shaped elements which are arranged on the glass element before the latter is subjected to the etching medium. It is also possible for a protective layer, a polymer layer for example, to be applied to the glass element before the latter is subjected to the etching medium. In that case it is possible for the protective layer to be applied over the full area of the first and/or second surface. The protective layer may subsequently be at least partially ablated again, by the laser, for example, if the protective layer was applied in advance of the structuring procedure by means of the laser, with the protective layer being removed accordingly in the region of the hole in particular. Hence, defined regions of the glass element may be masked by mounts, shaped elements and/or protective layers and in this way the glass element may be shielded from the etching medium. These mounts, shaped elements and/or protective layers are therefore of a material which is resistant to the etching medium. In this way, the mounts, shaped elements and/or protective layers are not attacked by the etching medium.

It may additionally be advantageous if the mounts, shaped elements and/or protective layers have a shape and/or structure which the elevations and/or plateau-like elevations to be generated are to have after the etching procedure. As a result, after the etching procedure, the elevations and/or plateau-like elevations can have a shape and/or structure corresponding to the shape and/or structure of the mounts, shaped elements and/or protective layers and/or configured complementarily thereto. In this way it is possible, for example, to generate a plateau-like elevation which runs at least partially around the glass element and so forms a reinforced margin.

Ideally, the mounts, shaped elements and/or protective layers have shielding holes which may in turn be configured as specific structures. In this way, indeed, it is conceivable for a structure to be generated on a plateau-like elevation. It is also possible, however, for the entire first and/or second surface of the glass element to be shielded by means of mounts, shaped elements and/or protective layers, and for the only regions left free to be those in which holes are generated, or in which damage sites or channels have been generated by the laser. In this way it is conceivable for the first and/or second surface to be configured substantially free of elevations, to generate in particular an average roughness value (Ra) of less than 40 nm, preferably less than 25 nm, and hence a particularly smooth surface. The glass element therefore preferably has at least one of the following features: the inside edge of the glass element has a multiplicity of domelike indentations, and the first and second surfaces of the glass element have a dome-free configuration, the inside edge of the glass element has a higher average roughness value (Ra) than the first and second surfaces of the glass element.

The surface of the glass element may therefore have a different roughness from the inside edge of the hole. Advantageously, therefore, the first and second surfaces of the glass element may be adjusted to a roughness which differs from the roughness of the inside edge of the hole. In this way it is possible to optimize the surfaces of the glass element and the inside edge of the hole for different intended applications. The roughnesses of the first and second surfaces are preferably adjusted in a joint method step, more particularly an etching step, with the roughness of the inside edge of the hole.

It is additionally conceivable for one of the surfaces to be shielded completely from the etching medium and for the other surface to be subjected completely, or at least partially, to the etching medium. Hence, for example, it is possible on one surface to generate a raised structure, with the raised structure being formed in particular by the elevations and/or plateau-like elevations. In other words, the glass element in this has elevations and/or plateau-like elevations only on one surface, while the other surface remains elevation-free. A different possibility is also of course for the first and second surfaces to be shielded, and for only the damage sites and/or channels to be subjected to the etching medium. In this way, both surfaces can be given a smooth configuration.

In one advantageous embodiment, the amount of material ablated from the glass element by the etching medium or etching procedure is such that channels or damage sites arranged alongside one another combine with one another, with the holes being generated in this way. In this case, preferably, walls between the channels, and/or damage sites, are ablated by the etching medium, to form a continuous edge. Furthermore, this edge ideally has domelike indentations. The edge may be formed, for example, as a glass element outside edge at least partially encompassing the glass element, or as a glass element inside edge at least partly encompassing the hole. In this way, large parts of the glass element, encompassed in the form of a structure by channels arranged alongside one another, before the etching procedure, can be dissolved out.

It would be possible, furthermore, to generate ribs on the edge that may possess a mechanical support function or act as crack inhibitors. These ribs are preferably arranged between pairs of channel centers. It is additionally conceivable for the depth and size and/or dimensions of the domes to be able to be altered through specific establishment of the ablation rate. For example, at a relatively high ablation rate, flatter and wider domes can be formed, and so the surface or the edge of the glass element can be given a smoother configuration. All in all, therefore, the method of the invention has the advantage that not only is it possible to generate holes with arbitrary shapes and dimensions but it is also possible in the same method step for the surface(s) of the glass element to be treated or worked. As a result it is possible at the same time to generate holes and to produce a matt surface having a high average roughness value, or a smooth surface having a low average roughness value. By means of the method, therefore, not only method steps but also considerable additional costs, due to possible reworking of the glass, are avoided.

It is also possible for the etching medium to be set in motion in such a way that the ablation rate is accelerated or reduced by the movement of the etching medium. The movement of the etching medium represents a further possibility for influencing, and more particularly for controlling, the ablation rate. By means of a movement it is possible for example for spent or saturated etching medium, or etching residues, to be transported away specifically from glass element regions to be etched, and to be replaced preferably by unused, fresh etching medium. In this way the ablation rate or etching speed can be accelerated considerably. Alternatively it is also conceivable for movement of the etching medium to be deliberately prevented, by means of separating walls in the container, for example. Accordingly, spent etching medium can no longer be transported away, and there is therefore a marked reduction in the ablation rate. With preference, however, the etching medium is set in motion and therefore the ablation rate is increased. A motion may preferably be induced mechanically. It is, however, also conceivable for the etching medium to be set in motion by a different physical route.

In the course of the method of the invention, at least one of the following possibilities is preferably selected: the movement is generated by sound waves, more particularly ultrasound waves. A sound wave source may be arranged below and/or to the side of the container in which the etching medium and also the glass element are located. A sound wave source has the advantage that only one sound wave source is sufficient to set the entire volume of the etching medium, more particularly of the etching solution, in motion. The waves generated propagate, without further input, throughout the solution volume, and are preferably attenuated only to a small extent, allowing the etching medium to be moved uniformly.

The movement is generated by magnetic stirrers or magnetic fields which are arranged preferably below the container. As a result of the magnetic fields, for example, magnetic stirring rods are set into an ideally rotational movement. In this case the magnetic stirrers and/or magnetic stirring rods are located within the etching medium and are therefore able to set the etching medium in motion directly through their rotational movement.

The advantage of a magnetically induced movement or of magnetic stirring bars is that the speed of the rotational movement and therefore the movement of the etching medium can be controlled very well. In this way, for example, a rapid or slow stirring movement can be applied to the etching medium. Furthermore, multiple magnetic stirrers may be controlled separately. In the case where two or more glass elements are located at the same time in the container and in the etching medium, it is possible through the separate control of the magnetic stirrers to establish different rotary speeds and therefore locally different movements and ablation rates. In this way, for example, multiple glass elements can be etched or processed synchronously at different speeds. It is of course also conceivable for the stirring bars to be configured as stirring units and to be moved not magnetically but instead, in particular, mechanically. For the purpose of stirring, moreover, these stirring units may simply be immersed into the etching medium from the direction of a container opening.

The movement is generated by mounts of the glass elements, or the mounts which hold the glass elements in the etching medium are set in motion mechanically. In this way, the glass element moves back and forth in the etching medium, and so a similar effect to that described above is produced.

The movement is generated via a shaker table, or the container together with the etching medium and the glass element is set in motion, for example, by arranging the container on a shaker table. By this means a uniform movement of the etching medium in the entire container is brought about.

The movement is generated by convection of the etching medium. In this case a heat source may be arranged under the container or to the side of the container. As a result of the one-sided heating, heated etching medium ascends and, elsewhere, colder etching medium drops, so generating a continuous convection. By this means it is possible to realize particularly slow movements, which lead to a reduced ablation rate.

The movement is induced by fluids, which are introduced into the etching medium through nozzles, for example. Such nozzles may be arranged on the container. This preferably generates an effervescence that sets the etching medium in motion.

In one advantageous embodiment, the etching medium is modified in at least one defined region at the surface of the glass element and the ablation rate is altered in this region relative to surrounding regions. This means that the ablation rate can be altered locally. In this way, advantageously, elevations can be generated specifically at individual or multiple holes. There are a number of possibilities for this purpose as to how the etching medium may be locally altered. Preferred in the sense of the invention, however, is one of the solutions stated below:

There are more open bonds in the glass material in the region of holes, edges, channels and/or damage sites. Moreover, there is a greater surface area there overall available for reaction with the etching medium. This results preferably in an ablation rate which is subject to short-term acceleration, or results in the ablation of more material within a shorter time span than on a planar surface of the glass element. As a result, preferably, the etching medium becomes spent comparatively quickly in the region of holes, edges, channels and/or damage sites, or its etching capacity greatly subsides, and etching residues are present particularly in these regions.

In these regions, therefore, as the etching time goes up, elevations can be generated, since at these points the material is preferably no longer ablated, or is ablated less rapidly, in relation to surrounding regions. In other words, elevations can be generated specifically in the region of holes and edges. Furthermore, through choice of the etching time, in other words of the time span in which the glass element is exposed to the etching medium, the height of the elevations can be adjusted. In this way it is possible in particular to generate annular elevations that preferably run around holes. These elevations later serve ideally as spacers of the glass element relative to a further component.

An effect of this kind—a temporary alteration of the ablation rate at holes and edges—can additionally be utilized in order to achieve a local alteration in the ablation rate and preferably in the etching medium as well, by deliberately altering the surface by laser in the course of etching at damage sites, channels, holes and/or edges. By selecting a pulse package with a plurality of pulses, such as 7 or 8 or more pulses per pulse package, for example, it is conceivable, for example, to bring about a particularly rough surface of the damage sites and/or channels. Hence the etching medium can be spent/neutralized more rapidly, and higher elevations can be realized in particular. Of course, conversely, it would also be possible to bring about a smoother surface of the damage sites and/or channels, by only a few pulses per pulse package—for example, 2 or 3—so that the etching medium is possibly spent or neutralized less rapidly and the elevations can preferably have only a low height. For this reason, the etching medium may equally be modified not just locally in the region of holes and edges but also at faces, especially inside faces of holes and/or edges.

Local supplying of fresh etching medium and/or additives. It is additionally possible to supply fresh etching medium or additives to the etching medium by, in particular, dripping such substances into the etching medium locally via a metering unit, such as a tap, for example. In this way it is possible not only to alter the etching medium locally but also, moreover, to set it in motion. Hence the ablation rate could be modified, preferably accelerated, further, and in particular in a controlled way.

A further possibility for a local alteration of the etching medium is offered by the materials of mounts of the glass elements, or of the container. Through a skillful choice of the material, of the container, for example, it is possible to release ablation-promoting ions, such as metals, or ablation-inhibiting ions, such as alkali metals, for example, into the etching medium and so to control the ablation rate. In this way it is possible for ablation-promoting or ablation-inhibiting ions to be released directly from the material of the mount of the glass element or of the container and for the etching medium, or its etching capacity, to be influenced.

It is also advantageous if the ablation rate is adjusted by generation of a spatial and/or temporal temperature gradient. Since the temperature influences the mobility of the physical constituents and more particularly the constituents that can be dissolved out of the material during the etching procedure, it is possible more advantageously with a change in the temperature to also alter the ablation rate or the reaction rate of the glass element with the etching medium. Hence, for example, a temporal temperature gradient may be controlled simply by way of a temporally defined variation in the temperature. The generation of a spatial temperature gradient is advantageous especially when, for example, multiple glass elements are to be etched separately with different ablation rates. There are different ways in which a spatial temperature gradient can be generated. Preference is given to one of the following possibilities:

A spatial temperature gradient may be generated between a container wall and an inside region of the container. In that case the container or the etching medium is heated evenly, meaning that the volume of the etching medium is heated uniformly. The etching medium is preferably cooled through the container wall. This cooling may be boosted by the container or the container wall having a material with a high thermal conductivity, such as a metallic material, for example. As a result, the heat of the etching medium is transported away more rapidly, so passively cooling the medium. It is, however, also conceivable for the container wall to be cooled actively by a cooling medium, water for example. In order to save on process costs, however, a thermally conductive container is preferred. This is also a source of the advantage, since no additional operating costs arise, allowing the temperature gradient to be generated simply and cost-effectively.

A further possibility is a heat source arranged locally at a container wall. This heat source may be arranged to the side, above and/or below the container. The temperature gradient is in that case formed concentrically, so to speak, around this heat source, and so the temperature decreases with increasing distance from the heat source.

One particular embodiment of the generation of the spatial temperature gradient is achieved by directing electromagnetic radiation, preferably a laser beam, locally onto the etching medium or a surface region of the glass element. This makes it possible in particular for a low-volume temperature gradient to be developed. As a result, a temperature gradient can be generated that encompasses, for example, only a few μm and is consequently able to act very locally. This has the advantage that the change in the ablation rate and/or in the etching medium that is brought about by the temperature can be confined to defined regions of the glass element, examples being individual holes. It is possible accordingly for, preferably, elevations at or around individual holes to be individually generated or prevented.

A further possibility is the heating of the mounts of the glass elements. If the mounts and hence, preferably, shielding elements as well are heated, the ablation rate can be altered particularly at those regions which directly border regions shielded by the mount. Hence it is possible to control the ablation rate at locations where plateau-like elevations and particular structures are to be produced.

Another possibility for the generation of a spatial temperature gradient as well is the generation of voltage arcs, or at least one voltage arc between two electrodes which may be placed at suitable locations in the etching medium. In the region of these voltage arcs, the etching medium then is heated locally, and in particular is also set in motion.

The ablation rate may alternatively be established by a specific spatial arrangement of the glass element within the etching medium, particularly with regard to gravity or to a movement direction of the etching medium. In order to accelerate the ablation rate within the hole, it is possible, for example, for the longitudinal direction of the hole in the glass element to be aligned parallel to the movement direction of the etching medium. In that case, therefore, the surface of the glass element is aligned transversely or perpendicularly to the movement direction of the etching medium. This alignment ensures that the etching medium is moved through the hole. As a result, for example, etching medium saturated with dissolved glass can be transported out of the hole, so making it possible at the same time to achieve a temporally consistently high ablation rate within the hole, since neutralized etching medium does not remain within the hole and, in particular, fresh, unsaturated etching medium is constantly available.

If, however, the etching medium is not set in motion actively, by one of the aforesaid possibilities, for example, the ablation rate in the region of the hole or edge of the glass element is initially increased as a result of a higher surface area in relation to the surface area of the glass element. However, the ablation rate in relation to the surface of the glass element also falls much more quickly in the region of the hole, since the etching medium is more quickly saturated or neutralized. With increasing saturation of the etching medium, there are increases in the density as well, because of the dissolved glass material, and hence also in particular in the weight of the etching medium. In the case of an alignment of the longitudinal direction of the hole in the direction of gravity, the heavy etching medium may also sink out of the hole. This may result in the development of an elevation at least partially around the hole and preferably in the direction of gravity or in the sinking direction or, generally, movement direction of the saturated etching medium. The saturation of the etching medium may mean that the ablation rate is reduced at least partially around the hole and preferably in the movement direction of the saturated etching medium, with the consequent development of an elevation.

On the other hand, however, an increased ablation rate may be produced on the side that is opposite the sinking direction or the movement direction, since fresh etching medium is supplied continuously there. Therefore, in particular solely as a result of the alignment of the glass element or of the hole within the etching medium, it is possible not only to bring about a movement of the etching medium but also to influence the ablation rate, preferably in the region of the hole.

Provision is therefore made to align the glass element within the etching medium, and in particular with respect to a movement direction of the etching medium, in such a way that saturated etching medium remains in the region of the intended points on the glass element, for the purpose of generating elevations and/or plateau-like elevations, and in particular is not transported away. For this purpose, the glass element or the surface(s) of the glass element may be aligned, for example, with respect to a container base and/or a movement direction of the etching medium, for example the sinking direction or flow direction, at an angle of between 0° (parallel) and 360° (parallel), preferably between 90° (perpendicular) and 270° (perpendicular). An angle of about 180° is also conceivable. Likewise, other angles too may be advantageous—for example, an especially slanting angle of the glass element relative to the movement direction of the etching medium, preferably of between 10° and 80°, more preferably between 20° and 70°, very preferably between 30° and 50°.

The ablation rate, particularly in the region of the hole, may also be controlled, furthermore, by the thickness of the glass element and/or the length of the hole. As outlined above, the etching medium becomes saturated more rapidly in the region of the hole and/or the movement of the etching medium is restricted by the narrower confinement of the hole walls. Both of these factors result in a reduced ablation rate in the region of the hole by comparison with the ablation rate at the surface of the glass element. Accordingly, there is a concentration gradient between the region of the hole and/or within the hole and a region at the surface of the glass element, and there is also, in particular, a temporal gradient in the ablation rate. Through a change in the length of the hole, thus in the thickness of the glass element, it is also possible, correspondingly, to change the movement of the etching medium in the region of the hole, and hence in particular also to change the concentration gradient or degree of saturation of the etching medium in the region of the hole. Through a suitable choice of the alignment of the glass element, and also, preferably, of other parameters as well, such as the movement of the etching medium and/or a temperature gradient, it is also possible for a ridge or elevation to be formed, for example, on one side of the glass element, at the edge, and for a ridge or an elevation to be avoided on the opposite side.

The glass element according to this disclosure may be used for applications including the production of components for hermetically packaging electro-optical components, microfluidic cells, pressure sensors and camera imaging modules.

### BRIEF DESCRIPTION OF THE DRAWINGS

The invention is elucidated below more accurately with reference to the attached figures. In the figures, identical reference signs designate elements that are in each case identical or corresponding.

FIG. 1 shows a schematic representation of the generation of a damage site in the glass element by a laser.

FIG. 2 shows a schematic representation of a glass element having multiple damage sites.

FIG. 3 shows a schematic representation of an etching procedure on the glass element.

FIG. 4 shows a schematic representation of the glass element in a state of advanced etching.

FIG. 5 shows a diagram of the average roughness value of the surface of the glass element after etching under different conditions.

FIG. 6 shows a diagram with measurement data for the ablation rate as a function of the glass concentration.

FIG. 7 shows results of measurement of the height of the elevation as a function of the temperature of the etching medium and of the alignment and shape of the hole;

FIG. 8 shows a schematic representation of an etching procedure on multiple glass elements in a container with moving etching medium;

FIG. 9 shows a diagram of the height of the elevation as a function of the movement of the etching medium.

FIG. 10 shows a glass element in overhead view with asymmetrical elevation and height profile of the elevation.

FIG. 11 shows a glass element in overhead view with asymmetrical elevation and two height profiles of the elevation.

FIG. 12 shows a glass element in overhead view with symmetrical elevation and height profile of the elevation.

FIG. 13 shows a result of surface measurement of an elevation on the surface of the glass element.

FIG. 14 shows two glass elements arranged one above the other.

### DETAILED DESCRIPTION

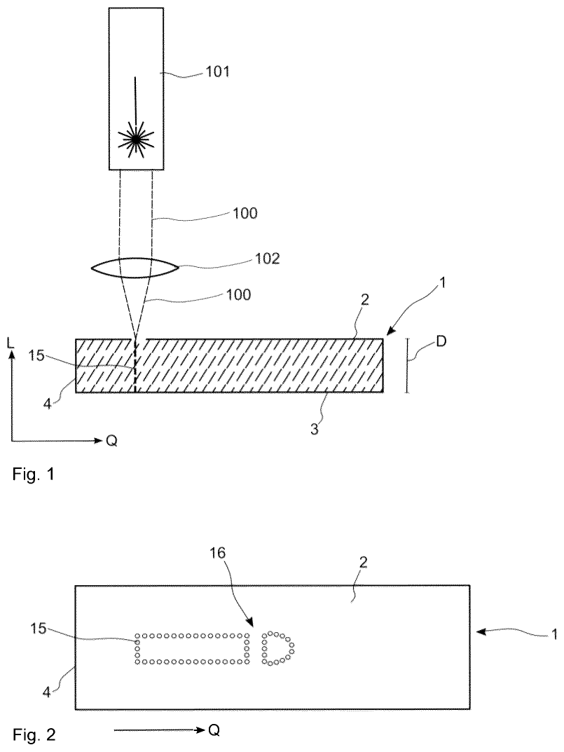

FIG. 1 shows schematically a glass element 1 having a first 2 and a second 3 surface, and also a thickness D. The first surface 2 here is arranged opposite and, in particular, preferably plane-parallel to the second surface 3. The glass element 1 also extends in a longitudinal direction L and a transverse direction Q. The glass element 1 preferably also has at least one side face 4, which ideally encompasses the glass element 1, and has a height corresponding to the thickness D of the glass element 1. Here, ideally, the thickness D of the glass element 1 and the height of the side face 4 extend in longitudinal direction L. The first 2 and second 3 surfaces may additionally extend in transverse direction.

In a first method step, a laser 101, preferably an ultrashort pulse laser 101, generates damage sites, more particularly channels 15, or channel like damage sites 15, in the volume of the glass element 1. For this purpose, a focusing optical system 102, such as a lens or a lens system, for example, focusses the laser beam 100 and directs it onto a surface 2, 3, preferably the first surface 2, of the glass element 1. As a result of the focusing, more particularly of a drawn-out focusing of the laser beam 100 onto a region within the volume of the glass element 1, the laser beam 100 energy that is irradiated as a result ensures that a filamentary damage site is generated which expands the damage site by means for example of multiple laser pulses, in the form of a pulse package, for example, to form a channel 15.

Preferably, as shown in FIG. 2, multiple channels 15 are generated in further steps, and ideally are arranged alongside one another in such a way that a multiplicity of channels 15 produce a perforation, and this perforation or this multiplicity of channels form outlines of a structure 16. In the best case, a structure 16 generated in this way corresponds to a shape of a hole that is to be generated. In other words, the distance and the number of channels 15 is selected such that outlines of holes to be generated are formed.

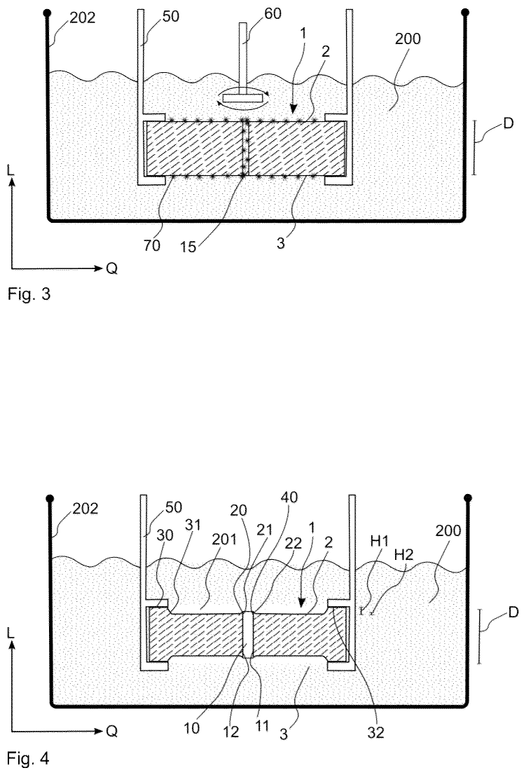

A further step is shown by FIG. 3. The glass element 1 is arranged detachably on mounts 50. The glass element 1 here may merely lie on the mounts 50, or may be or have been fixed to them. With preference, certain regions of the mounts 50 serve to cover or to shield defined regions of the glass element 1. This purpose, however, may also be served by other elements, such as one or more polymer layers or shaped elements, for example. The regions that are covered by the mounts, by the polymer layer(s) and/or by the shaped elements serve preferably as a mask for a raised structure to be generated on the surface 2, 3 of the glass element 1. Equally, however, it is also conceivable for the first and/or second surface 2, 3 to be shielded completely, in order to avoid a raised structure in the surface of the glass element, and to generate at least one particularly flat or planar surface. It is of course also possible to cover such regions before the laser 101 is employed. The covered regions are intended additionally to act as a shield with respect to an etching medium to which the glass element 1 is exposed in a subsequent step.

For this purpose, the glass element 1 is held by means of the mounts 50, and more particularly immersed, into an etching medium 200, preferably an etching solution, which is arranged preferably in a container 202. Ideally, the container 202 for this purpose comprises a material which is substantially resistant toward the etching medium 200. The container preferably comprises a material which is able to release certain elements or substances, such as certain ions or molecules, for example, into the etching medium 200. In the best case, these substances released by the container 202 alter the etching capacity of the etching medium 200 in such a way as to accelerate or reduce an ablation rate of material of the glass element.

The etching medium 200 used is preferably an acidic or alkaline solution, and more particularly an alkaline solution, KOH for example. In the best case, the etching capacity of the etching solution is influenced by the material of the container 202, and possibly also by additives which have been added to the etching solution. Exposure of the glass element to the etching medium 200 causes material of the glass element to be ablated, thereby producing an ablation 70 and also an ablation rate which can be influenced by a number of factors.

A first factor is the temperature at which the glass element 1 is etched. The etching procedure is carried out preferably at a temperature of between 60° C. and 130°, ideally at about 100° C., which generates preferably a temperature gradient by virtue of a container wall which is cooler in relation to the heat source.

In addition, the ablation rate is preferably influenced, more particularly accelerated, by the setting into motion of the etching medium 200. For example, one or more stirring units 60 may be employed for this purpose. It is conceivable to use mechanically or electronically driven stirring units 60, stirring bars for example, or else magnetic stirrers which are controlled via a magnetic field. In the best case, the stirring units 60 are operated in such a way that they perform a rotational movement and thereby set the etching medium in motion.

In a further embodiment, the container 202 may be subdivided into multiple regions, by means of at least one dividing wall, for example. Utilized preferably in this case is a dividing wall 51 which subdivides the container 202 into two regions. In a first region, it is then possible, for example, for one or more stirring units 60 to be arranged, and in a second region preferably one or more glass elements 1 are arranged. In this case, the dividing wall 51 preferably has one or more passages which connect the first region to the second region in such a way as to enable an exchange of the etching medium 200 through the passages. The etching medium 200 can be set in motion in a targeted way by this means, and more particularly it is possible by this means to realize—or control—a defined flow direction of the etching medium 200.

FIG. 4 shows, schematically, the etching procedure from FIG. 3 at an advanced point in time. Furthermore, during the etching procedure shown in FIG. 4, no stirring unit 60 has been used, and so the etching medium 200 has not been set in motion. As a result, it has been possible for the etching medium 200 to be neutralized more rapidly at regions at which the ablation rate was heightened, meaning that the etching medium 200 is spent at these regions. A spent etching medium 201 of this kind is represented in FIG. 4 in the region of the first 2 and second surfaces 3. Overall, material has been ablated at the regions not shielded by the holding elements 50. This relates essentially to the channels, but may also relate to particular regions of the first 2 and/or second 3 surface. In this procedure, channel walls of multiple channels have been ablated preferably to an extent such that two or more channels have been united, thereby generating the hole 10.

In the example of FIG. 4, a glass element 1 is represented in which the etching has generated a raised structure—that is a glass element 1 with raised structure is depicted. This raised structure is formed on the one hand by plateau-like elevations 30, which have been generated particularly at the marginal regions of the glass element 1 as a result of shielding by the mounts 50, and on the other hand the raised structure is formed by elevations 20 developed preferably around the hole 10. These elevations 20 have an inside face 20 and an outside face 22, which are at an acute angle to one another. Additionally, the hole 10 has an inside hole face 12 which is preferably defined such that the inside hole face 12 surrounds the hole 10 completely in at least two spatial directions. The hole 10 here may extend in longitudinal direction L and transverse direction Q, and in particular form a length which extends along the longitudinal direction L and transversely to the first 2 and/or second 3 surface. It is possible for the length of the hole 10 and a height H2 of the elevation to correspond jointly to a thickness D of the glass element 1. Equally, however, it is also possible for the length of the hole 10 to correspond to the thickness D. Furthermore, the hole 10 forms an edge 40, particularly in the region of the inside hole face 12, that has domelike indentations.

The plateau-like elevations 30 may have flanks 31 which are arranged at an obtuse angle to the first 2 and/or second 3 surface of the glass element 1, in which case a shape or a plateau of the plateau-like elevations 30 corresponds ideally to a shape of the mounts 50 and this shape corresponds in turn to a shape of the shielded regions. A height H1 of the plateau-like elevations 30 here may be less than the thickness D of the glass element 1, and may preferably run parallel to the thickness D.

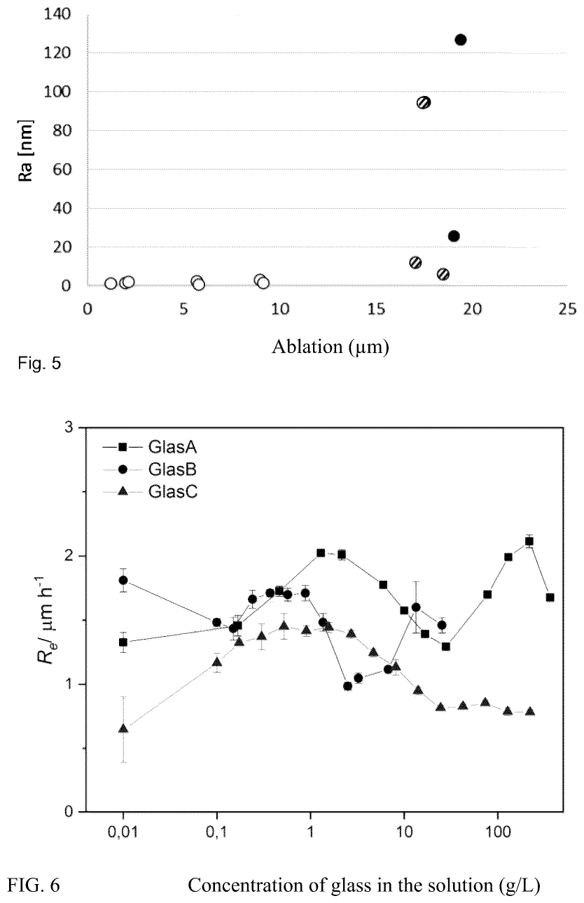

FIG. 5 shows a measured average roughness value (Ra) of the surface of the glass element 1, on the y-axis, as a function of the ablation (removal) on the x-axis, under different etching conditions. The respective etching conditions are represented by the different measurement results.

The measurement results represented as empty black rings stand for an etching procedure in which the etching medium 200 has been set in motion in particular by at least one stirring unit 60. Furthermore, a container 202 has been used which preferably comprises a metallic material.

The measurement results represented as solid black circles stand for an etching procedure in which the glass element 1 has been shielded from the etching medium 200 at least partially, and preferably by a polymer layer, specifically perfluoroalkoxy polymers. In addition, the etching medium 200 has not been actively set in motion.

The measurement results represented as patterned black rings stand for an etching procedure in which the glass element 1 has been shielded from the etching medium 200 at least partially, and preferably by a polymer layer, specifically perfluoroalkoxy polymers. Furthermore, a container 202 preferably comprising a metallic material has been used, and the etching medium 200 has not been set in motion.

Considering these results, it is seen that the surface 2, 3 of the glass element 1 has a particularly low average roughness value after an etching procedure in which the etching medium 200 is set in motion. This average roughness value is preferably between 2 nm and 10 nm, and so the glass element 1 has a particularly smooth surface 2, 3, and the movement of the etching medium 200 leads preferably to a very low average roughness value. It is also seen that under these conditions the ablation of material, at less than 10 μm, is very low, and that only a low ablation is necessary in order to generate a low average roughness value.

It can be established, furthermore, that the use of shielding relative to the etching medium leads to a significantly higher average roughness value and hence to a significantly rougher and/or matter surface 2, 3 of the glass element. In other words, after an etching procedure without movement of the etching medium 200, the glass element 1 has a significantly rougher surface than after an etching procedure with movement of the etching medium 200. The average roughness value after an etching procedure with moving etching medium 200 is preferably between about 5 nm and 130 nm. It is also evident from the results that a significantly higher ablation is necessary in order to generate a surface 2, 3 having higher average roughness values, in other words a rough and/or a particularly matt surface 2, 3. The ablation in such a case is preferably higher than 15 μm.

Since in a number of cases, that is both with movement and without movement of the etching medium 200, a container 202 having a metallic material was used, this seems to have little effect on the roughness of the surface 2, 3.

FIG. 6 shows measurement data for the ablation rate (Rₑ in μm/h) as a function of the glass concentration (g/liter) in the etching medium 200 in the region of the hole for three different glasses: glass A, glass B and glass C. The diagram illustrates that an ablation gradient develops during the ablation or etching. Particularly in the case of glass A and glass C, the ablation rate increases at the start, first moderately and then strongly, with an accompanying increase in the glass concentration in the etching medium 200. As soon as a certain concentration value has been reached, therefore, the etching medium reaches a certain saturation, and the ablation rate falls for all three glasses.

In the case of glass C in particular it is clearly apparent that the ablation rate, after saturating has been reached, falls to a value which is roughly consistently low. This may be explained by an initial sharp increase in the glass concentration in the etching medium 200 in the region of the hole 10 and by the etching medium 200 with a high glass concentration subsequently remaining in the region of the hole 10, or not being transported away. This is probably attributable to a density of the glass-enriched etching medium 200 that is comparable with a density of the etching medium 200 with a low glass concentration. As a result, there is little or no movement of the etching medium 200 in the region of the hole 10, and so etching medium 200 with high glass concentration is not transported away. The glass concentration of the etching medium, accordingly, is higher in the region of the hole than at the surface 2, 3 of the glass element.

The situation with glass B and glass C is different. When the ablation rate reaches a high value and initially decreases again as the glass concentration goes up, there is again an increase in the ablation rate on attainment of a low value. This may be explained by the glass-enriched etching medium 200 in the case of glass B and glass C having a higher density, and therefore being heavier, than the etching medium 200 with low glass concentration. The etching medium 200 with high glass concentration therefore sinks (in the case of alignment of the surface of the glass element parallel to a container base) out of the region of the hole 10, allowing fresh etching medium 200 to enter into the region of the hole again. The fresh etching medium then also permits an increasing ablation rate again, which drops once more as soon as the glass concentration of the etching medium 200 again reaches a critical value. Overall, this effect can be utilized for targeted control of the ablation rate and for the establishment of a desired gradient of the ablation rate, for example, by alignment of the glass element 1 correspondingly in the etching medium 200, or by movement of the etching medium 200 in a defined direction. In this way, therefore, regions with high glass concentration, at which preferably elevations 20 are formed because of the reduced ablation rate, can be generated in a targeted way.

In other words, the formation of elevations 20 with a height H2 and/or a shape controlled in a targeted way by a defined glass concentration of the etching medium 200, and hence the ablation rate can be controlled, this control more particularly being local.

In general without restriction to the measurement results represented, the elevation, and in particular a height H1, H2 and/or shape of the elevation 20, may therefore be authoritatively influenced by the operating parameters—for example, the ablation rate, the composition of the etching medium 200, more particularly the glass concentration of the etching medium 200, the movement of the etching medium 200 and, preferably, a defined flow direction, the duration of the etching procedure and/or the temperature of the etching medium 200.

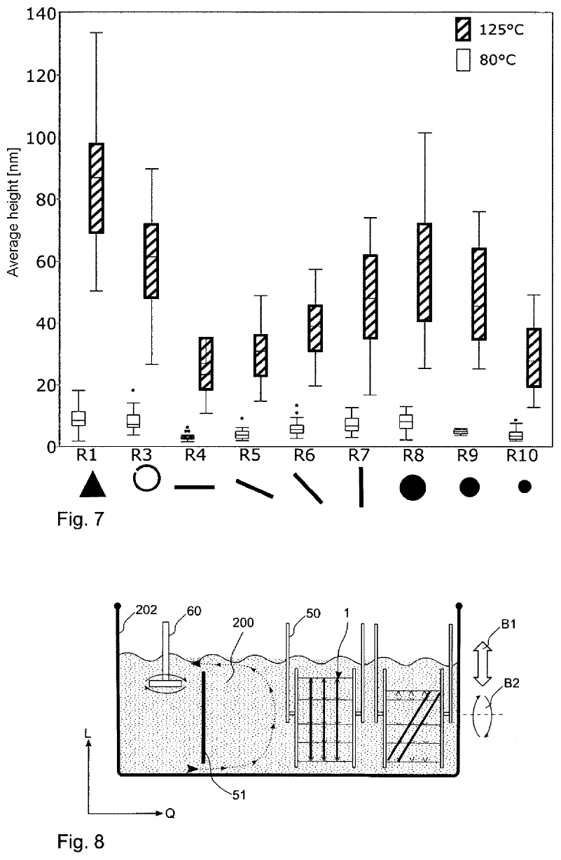

FIG. 7 in this regard shows the influence of the temperature on the ablation rate. Measurement results are shown for the height H2 of the elevation 20 as a function of the temperature of the etching medium 200 and the shape of the hole 10. The different shapes are therefore entered under the x-axis. The movement direction of the etching medium 200 in this case was aligned parallel to the first and second surfaces 2, 3. It can be seen that the elevation 20 is more highly pronounced, for all shapes and/or structures of the hole 10, if the etching medium 200 has a temperature of, for example, 125° C., in comparison to an etching medium having a temperature of 80° C. Without restriction to the illustrative structures shown, therefore, the height H2 of the elevation 20, more particularly at least partially around the hole 10, can be authoritatively controlled by adjusting the temperature of the etching medium.

Since the ablation rate increases at elevated temperature, more material is dissolved as well. As a result of this, the etching medium 200 is saturated more rapidly around a region with high ablation, more particularly the hole 10, and as a result the ablation rate falls rapidly in this region. In general, therefore, the height H2 of the elevation 20 scales with the ablation or the ablation rate. The higher the ablation, the higher the height H2 of the elevation 20. However, the ablation rate in regions without a hole 10, such as in the region of the first and second surfaces 2, 3, for example, remains substantially higher than in the region around the hole 10. In other words, the ablation rate can be adjusted in such a way that the ablation rate is higher in one region of the glass element 1 than in another region—for example, at least partially around the hole 10.

Depending in particular on the established movement of the etching medium 200 and/or of the mount 50, the elevation 20, particularly around the hole 10, may have asymmetric shaping or be asymmetrically shaped. In a further embodiment, however, the elevation 20, particularly around the hole 10, may also have symmetrical shaping/be symmetrically shaped. In that case the hole 10 itself as well is symmetrical with respect to an axis of rotation parallel to the longitudinal direction L. Symmetrical is understood in the sense of the invention such that the elevation 20, more particularly around the hole, has substantially a unitary height and/or a unitary shape—slope, for example. Asymmetric in this sense therefore means that the elevation 20, particularly around the hole, has different heights and/or slopes at least in some sections.

From FIG. 7 it is also possible to read off a further effect. Particularly in the case of the elongate form of the hole, the size of the height deviation is dependent on the orientation relative to the movement direction. For instance, in the case of the elongate shape, as the etching bath flows over transversely to the longitudinal direction (3^{rd} measurement value from the left), the height deviation is much lower than in the case of bath flow over in the longitudinal direction (6^{th} measurement value from the left). The reason for this is thought to be the time required by the liquid of the etching medium in order to traverse the hole. In the case of the 3^{rd} measurement value from the left, the time is much shorter than in the case of the 6^{th} measurement value from the left. According to one embodiment of the invention therefore, a desired height deviation may be established, generally, by adjusting the time for the etching medium to flow over the hole and/or through the orientation of the hole relative to the movement direction, or flow direction.

FIG. 8 represents, schematically, a further embodiment. Without restriction to the example represented, a flow direction of the etching medium 200 can be mandated by means of a divided container 202. In this example, the etching medium 200 is set in motion by means of a stirring unit 60, such as a propeller or magnetic stirrer, for example. The region having the stirring unit 60 here may be separated for example by a dividing wall 51 spatially and at least partially from a second region in which the glass element 1 or, preferably, two or more glass elements 1 is or are arranged, more particularly in a mount 50. In the example shown in FIG. 8 there are multiple mounts, more particularly two mounts 50 arranged, each with multiple glass elements 1, in the second region. The dividing wall 51 preferably has one or more passages which connect the first region to the second region in such a way as to enable exchange of the etching medium 200 through the passages. In this way, a movement or circulation, more particularly convection, of the etching medium 200 in the second region can be achieved, the convection being represented as a dashed line. The mounts are preferably implemented in such a way that they can be set in motion, more particularly such that the glass elements 1 within the etching medium are movable. For this purpose, FIG. 8 represents two possible movements B1, B2 of the mounts 50 or of the glass elements 1. B1, for example, shows an up-and-down movement of the glass elements 1 or of the mounts 50. Relative to the container base, therefore, the glass elements 1 may be moved up and down, more particularly in a constant cycle, with a constant frequency and/or a constant distance, for example. The distance of the up-and-down movement here may be varied as desired as a function of the length of the glass elements 1, their alignment, and the height of the container 202. In general, therefore, the glass element 1 may be moved in the etching medium along a path with at least one reversal of direction.

Another form of the movement of the glass elements 1 or the mounts 50 is represented by a rotary movement B2. The mounts 50 may also therefore be configured such that the glass elements 1 are rotated or rotatable about at least one axis. With preference, the glass elements 1 are also rotatable or capable of being rotated about a second axis, which is preferably arranged perpendicular to the first axis.

In general, according to one embodiment, the holder as a whole may be moved on a generally closed—for example, rectangular/polygonal/elliptical—path without rotating about its own axis. As a result, even in the case of a closed pathway of this kind, it is possible to prevent locally different flow attack rates of the etching medium on the glass elements as a result of a rotation. In general, then, it may be advantageous if the glass element 1 is moved without rotation in one or more spatial directions or combinations thereof in the etching medium.

Especially in combination between the movement of the glass element 1 and a movement of the etching medium 200, the raised structure or the elevation 20 or elevations 20 may be symmetrically or asymmetrically shaped. A symmetrical elevation 20 may be achieved, for example, by rotating the glass element 1 about an axis which is arranged transversely, more particularly perpendicularly, to the movement direction of the etching medium 200. The glass element 1 may be rotated preferably about an axis which is aligned perpendicularly to the first and/or second surface 2, 3. A further possibility for the configuration of a symmetrical structure or elevation 20 is an up-and-down movement of the glass elements 1, preferably with the etching medium 200 unmoved. In the case of an unmoved or nonuniformly moved etching medium 200, the glass elements 1 are preferably rotated about two axes which in particular are perpendicular to one another, in order to generate a symmetrical elevation 20.

An asymmetric structure or elevation 20, conversely, can be generated if the etching medium 200 and/or the glass-enriched etching medium 200 is in motion. In this case, the elevation 20 is developed preferably in the movement direction or sinking direction of the etching medium 200, since the glass-enriched etching medium 200 leads locally to a reduced ablation rate.

A further control parameter is formed by the alignment of the glass elements 1 in the etching medium. As represented in FIG. 8, the glass element 1 or two or more glass elements 1 may be aligned, preferably vertically, transversely or perpendicularly with respect to the container base. It is possible accordingly to align the glass elements 1 with respect to a movement direction of the etching medium, in particular in order to control the formation and/or shape of at least one elevation 20. In the right-hand mount 50, for example, the glass elements 1 are aligned slantingly with respect to the container base and/or to the movement direction of the etching medium 200. By these means it is possible preferably to generate eddies of the etching medium 200, at particular edges of the glass elements 1, for example. In such a case, an accelerated ablation rate may even be realized through the rapid transporting-away of the glass-enriched etching medium 200 by virtue of the eddies, in particular locally.

The slant of the substrates in relation to the flow direction of the etching medium generally alters the flow conditions/flow velocities between the two sides.

In this case, relative to the first and/or second surface 2, 3, an indentation can be generated, preferably at least partially around the hole 10.

In a further embodiment, the glass elements 1 may be aligned substantially parallel to the container base or, preferably, horizontally. In this case, glass-enriched etching medium 200 is able to sink through the holes 10 and be distributed uniformly in particular around the holes, allowing a symmetrical elevation 20 to be generated at the surface 2, 3 arranged opposite the container base. In contrast to this, on the surface 2, 3 facing away from the container base, it is possible not to form any elevations 20, or at least to form elevations 20 which have a lower height H2. For example, the first surface 2 faces the container base, and in that case the elevation 20 is generated on the first surface 2. On the second surface 3, lying opposite the first surface, conversely, elevations 20 with a lower height H2 are generated.

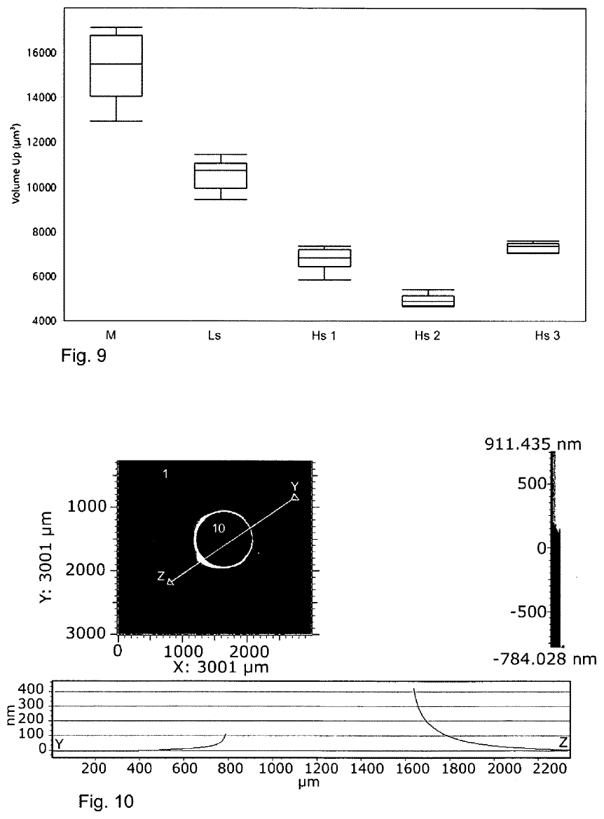

FIG. 9 in this regard shows, in a diagram, the relationship of the height H2 of the elevation 20, indicated as volume in μm³, as a function of the movement of the etching medium 200. Five samples, or glass elements 1, are represented, which have been etched with the etching medium 200 moving to different extents. The etching medium here was set in motion, using a magnetic stirrer or stirring flea, at moderate or normal circulation of 120 revolutions per minute (measurement value “M”), with a low stirring movement of 50 revolutions per minute (measurement value “Ls”) and with a strong stirring movement of 400 revolutions per minute (repetition measurement, measurement values “Hs1”, “Hs2”, “Hs3”). It is clear that the three glass elements 1 which were etched with a strong stirring movement Hs exhibit a low volume of the elevation 20, i.e., in particular, an elevation 20 with a lower height H2 than the glass elements 1 etched at a weaker stirring movement. By means of a strong circulation of the etching medium 200, accordingly, it is possible to reduce the height H2 of the elevation 20. Conversely, the elevation 20 can be heightened if the etching medium 200 is set in motion only weakly or not at all.

One example of a glass element 1 produced by means of the technique elucidated above is represented in FIG. 10. The measurement data/topography of the substrate surface around the hole, shown here, were recorded on a pixel basis using a white-light interferometer, and the results of the evaluation have been represented as a gray-scale image (top half of FIG. 10). The glass element has an asymmetric structure or elevation 20. In the top part of FIG. 10, the glass element 1 is represented in an overhead view, with the glass element 1, particularly in the detail shown, having a hole 10, preferably with a diameter of about 800 μm. The height values of the asymmetric structure, or of the elevation 20, are represented, as stated, as gray values, which can be estimated and/or read off by means of the gray value scale at the right-hand margin. The shape of the asymmetric structure, or the shape of the elevation 20, is therefore apparent clearly from the pale gray values, or the area represented substantially in white, in particular around the hole 10.

In the image there is additionally a line Y-Z represented. The height profile along this line, computed from the data and interpolated, is represented in the graph below the image. This line Y-Z was placed transversely over the hole 10. The height profile computed from the data and interpolated along this line Y-Z is represented in the graph below the image. From the height profile or topography of the elevation 20, which is shown in the bottom part of FIG. 10, it is easily possible to read off an asymmetric character of the elevation 20. The missing values between about 800 μm and about 1600 μm represent the hole 10. It is clearly apparent that in the rear region of the line scan, more particularly in the section between 1600 μm and 2200 μm, the elevation 20 is much more strongly pronounced, or has higher values, than in the front section from 200 μm to 800 μm.

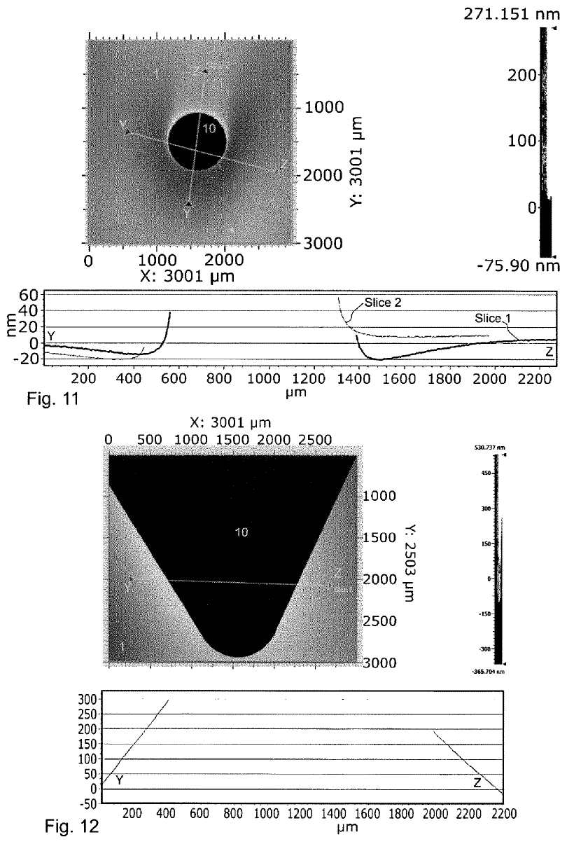

In analogy to the form of representation from FIG. 10, a further embodiment is represented in FIG. 11. In this case, the topography captured by white-light interferometry has been illustrated using two height profiles. A first height profile, denoted slice 1, was made here substantially transversely to a second height profile, which is referred to as slice 2. In this example as well, the glass element 1 has an asymmetric structure, which may be configured as an elevation 20 or else as a sink. From the height profile in the lower region of FIG. 11 it is evident that the structure in the region of the first line scan along first forms a sink and, as the distance from the hole 10 becomes lower, changes into an elevation 20, with the slope increasing essentially in the direction of hole 10, in particular such that local minima are formed at each side of the hole 10, or at least partially around the hole 10. From the second line scan, the strong asymmetric character of the structure is particularly readily apparent, with the structure in the front section of the scan, up to about 420 μm, being configured as a sink and in the rear section, in particular on the side opposite the front section, beyond about 1300 μm, being configured as an elevation 20.

FIG. 12 shows a further embodiment of a glass element 1. The glass element 1 has a substantially symmetrical structure, or symmetrical character of the elevation 20. In the view represented, the elevation 20 is arranged around the hole 10. The hole 10 in this example is shaped in such a way that it has a width which decreases toward the lower margin of the image, preferably such that the hole 10 is shaped as a peak. The height of the elevation 20 increases in the direction of the hole, as is apparent from the light shades, and also from the height profile of the line scan Y-Z that is represented. The image detail shown, however, is small, and so the line scan captures only part of the elevation 20, more particularly the topography of the glass element 1.

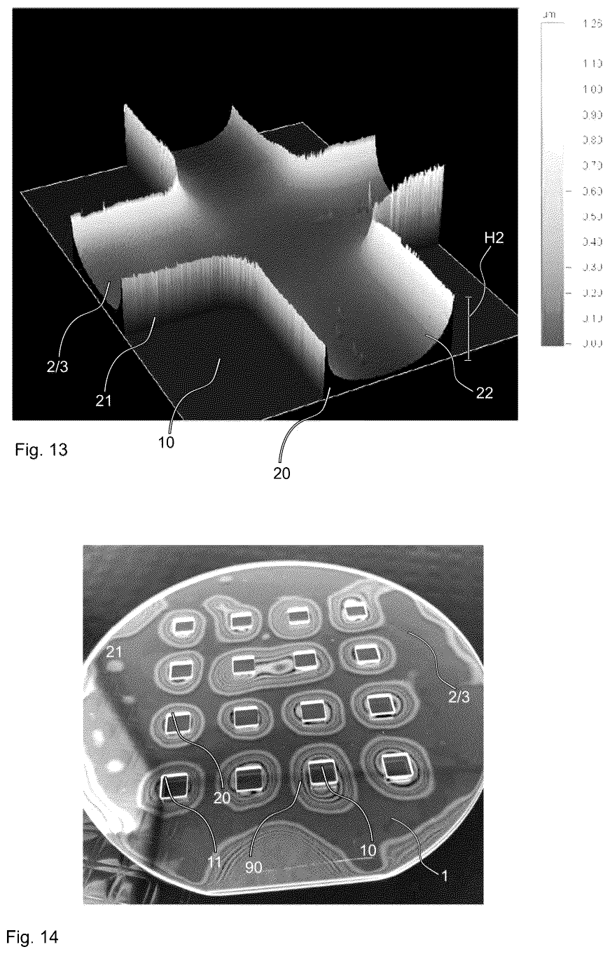

FIG. 13 shows a topography measurement of the surface 2, 3 of the glass element 1. Here, the bar on the right-hand side shows the deviation or the height H2 of the elevations 20 relative to the surface 2, 3. These elevations 20 can clearly be seen to be arranged around holes 10, and the outside face 22 of the elevation 20 is preferably at an obtuse angle to the surface 2, 3 of the glass element 1. Furthermore, the inside face 21 of the elevation ideally forms an acute angle with the outside face 22. In this example, the outside faces 22 of the elevation 20 transition smoothly into the surface 2, 3 of the glass element 1. This means that macroscopically there is no clearly defined transition between the outside faces 22 of the elevation 20 and the surface 2, 3 of the glass element in evidence. Furthermore, the example of FIG. 6 shows that multiple elevations 20 together form a raised structure on the surface 2, 3, said structure being configured here more particularly as a cross structure between four elevations 20, or between multiple holes 10.

Represented in FIG. 14 is a glass element 1 which has been produced by the method of modifying the surface 2, 3 and which is arranged on a glass plate. Around the holes 10 in the glass element 1 produced by the method, there are elevations 20. As a result of the elevations 20, around the elevations 20, there is an altered distance generated between glass elements 1 and the glass plate, or an altered thickness of the fluid layer between glass plate and glass element 1. This altered thickness leads in turn to different refraction of light at the two interfaces of the fluid layer with the two glass elements, with interference of the wavelengths of said light, resulting in the Newtonian rings that are observed. In other words, the Newtonian rings that are observed show, in a simple way, the presence of the elevations 20. As can be seen, these elevations 20 run in particular annularly around the holes 10. Since the Newtonian rings are not interrupted, the elevations 20 surround the holes 10 completely.

### LIST OF REFERENCE SIGNS

1 platelike glass element
2 first surface
3 second surface
4 side face
10 hole
11 wall of the hole
12 inside hole face
15 channel/passages
16 structure
20 elevation
21 inside face of the elevation
22 outside face of the elevation
30 plateau-like elevation
31 flanks of the plateau-like elevation
32 plateau
40 edge
50 mounts
51 dividing wall
60 stirring unit
70 ablation/etching procedure
90 Newtonian rings
100 laser beam
101 laser/ultrashort pulse laser
102 focusing optical system
200 etching medium
201 spent etching medium
202 container
L longitudinal direction
Q transverse direction
H1 height of the plateau-like elevation
H2 height of the elevation
B1, B2 movement of the mounts
D thickness of the glass element

What is claimed is:

1. A platelike glass element, comprising:
a first surface;
a second surface opposite the first; and
a hole that perforates the first surface, wherein the hole extends in a longitudinal direction and a transverse direction, the longitudinal direction is transverse to the first surface,
wherein the first surface, at least partially around the hole, has an elevation with a feature selected from a group consisting of: a height of less than 5 μm that at least partially around the hole, a height greater than 0.05 μm, a height greater than 0.5 μm, a height greater than 1 μm, a height greater than 10 μm, a height less than 20 μm, a height less than 15 μm, a height less than 12 μm, and combinations thereof, and
wherein the first surface has an average roughness value that is greater than 15 nm and less than 100 nm.

2. The platelike glass element of claim 1, wherein the average roughness value is greater than 40 nm and less than 60 nm.

3. The platelike glass element of claim 1, wherein the hole perforates the second surface.

4. The platelike glass element of claim 1, wherein the elevation has a feature selected from a group consisting of: to plateau-like elevation shape, completely surrounds the hole, a side of the elevation facing the hole is an extension of a wall of the hole, an inside face that faces the hole being at an acute angle to an outside face that faces away from the hole, an outside face that faces away from the hole being at an obtuse angle to the first surface, dimensions along the longitudinal direction that are greater than 5 μm, dimensions along the longitudinal direction that are greater than 8 μm, dimensions along the longitudinal direction that are greater than 10 μm, dimensions along the longitudinal direction that are less than 5 mm, dimensions along the longitudinal direction that are less than 3 mm, and dimensions along the longitudinal direction that are less than 1 mm, and combinations thereof.

5. The platelike glass element of claim 1, further comprising a thickness selected from a group consisting of greater than 10 μm, greater than 15 μm, greater than 20 μm, less than 4 mm, less than 2 mm, less than 1 mm, and combinations thereof.

6. The platelike glass element of claim 1, wherein the hole has a wall with a multiplicity of domelike indentations.

7. The platelike glass element of claim 1, wherein the hole is a channel that extends through the glass element from the first surface to the second surface and perforates both the first and second surfaces.

8. The platelike glass element of claim 7, wherein further comprising a plurality of the channels that directly border one another to define an edge, the edge being an outside edge or an inside edge.

9. The platelike glass element of claim 1, wherein the elevation has a height that runs parallel to the longitudinal direction and transverse to the first surface.

10. The platelike glass element of claim 1, wherein the elevation has a symmetrical shape or an asymmetrical shape.

11. The platelike glass element of claim 1, further comprising an inside edge with a multiplicity of domelike indentations, wherein the first and second surfaces have a dome-free configuration.

12. The platelike glass element of claim 1, further comprising an inside edge with a second average roughness that is higher than the average roughness of the first surface.

13. The platelike glass element of claim 1, wherein the glass element is configured for a use selected from a group consisting of a hermetically packaging electro-optical component, a microfluidic cell, a pressure sensor, and a camera imaging module.

14. A method for modifying a surface of a platelike glass element, comprising:
providing the glass element;
generating a filamentary channel in a first surface of the glass element using a laser beam from an ultrashort pulse laser, the filamentary channel having a longitudinal direction that is transverse to the first surface; and
widening the filamentary channel with an etching medium to ablate glass of the glass element at an adjustable ablation rate to form a hole in the glass element,
wherein the etching medium generates a features in the first surface selected from a group consisting of: an elevation in the first surface at least partially around the hole with a height of less than 5 μm, a plurality of plateau-like elevations with a height of greater than 0.05 μm, a plurality of plateau-like elevations with a height of greater than 0.5 μm, a plurality of plateau-like elevations with a height of greater than 1 μm, a plurality of plateau-like elevations with a height of greater than 10 μm, an average roughness value of greater than 15 nm, an average roughness value of greater than 25 nm, an average roughness value of greater than 40 nm, an average roughness value of less than 100 nm, an average roughness value of less than 80 nm, an average roughness value of less than 60 nm, and combinations thereof.

15. The method of claim 14, wherein the etching medium has an ablation rate that is accelerated or reduced by motion of the etching medium and the glass element with respect to one another.

16. The method of claim 15, further comprising moving the glass element in a direction selected from a group consisting of: without rotation in one or more spatial directions or combinations thereof in an etching bath of the etching medium, along a path with at least one inversion of direction, rotated about an axis arranged transversely to a movement direction of the etching medium, and rotated about an axis aligned perpendicularly to the first second surface.

17. The method of claim 14, further comprising modifying the etching medium in at least one region so that the ablation rate is altered in the at least one region relative to remaining regions.

18. The method of claim 17, wherein the step of modifying the etching medium comprises generating a spatial and/or temporal temperature gradient.

19. The method of claim 17, wherein the step of modifying the etching medium comprises changing a spatial arrangement of the glass element within the etching medium.

20. The method of claim 17, wherein the step of modifying the etching medium comprises selecting a combination of glass composition and a composition of the etching medium.
